(19) United States
(12) Patent Application Publication
(10) Pub. No.: US 2025/0133755 A1
(43) Pub. Date: Apr. 24, 2025

(54) CAPACITOR DEVICE AND MANUFACTURING METHOD THEREOF

(71) Applicant: United Microelectronics Corp., Hsinchu (TW)

(72) Inventor: Shin-Hung Li, Nantou County (TW)

(73) Assignee: United Microelectronics Corp., Hsinchu (TW)

(21) Appl. No.: 18/498,049

(22) Filed: Oct. 31, 2023

(30) Foreign Application Priority Data
Oct. 18, 2023 (TW) 112139738

(51) Int. Cl. H01L 21/02; H01L 21/768

(52) U.S. Cl. CPC H10D 1/692; H01L 21/022; H01L 21/76816; H01L 21/76829; H01L 21/76877

(57) ABSTRACT

Provided are a capacitor device and a manufacturing method thereof. The capacitor device includes a first electrode, a second electrode, an insulating layer, a first dielectric layer, a second dielectric layer, a third electrode and a fourth electrode. The first electrode is disposed on a substrate. The second electrode is disposed on the first electrode. The insulating layer is disposed between the first electrode and the second electrode. The first dielectric layer is disposed on the substrate and covers the first electrode, the second electrode and the insulating layer. The second dielectric layer is disposed on the first dielectric layer. The third electrode and the fourth electrode are disposed in the second dielectric layer and separated from each other. The third electrode is electrically connected to the first electrode, and the fourth electrode is electrically connected to the second electrode.

### CROSS-REFERENCE TO RELATED APPLICATION

This application claims the priority benefit of Taiwan application serial no. 112139738, filed on Oct. 18, 2023. The entirety of the above-mentioned patent application is hereby incorporated by reference herein and made a part of this specification.

### BACKGROUND

### Technical Field

The present invention relates to a capacitor device, and in particular to a capacitor device including a metal-insulator-metal (MIM) capacitor configuration and a metal-oxide-metal (MOM) capacitor configuration or the like.

### Description of Related Art

In semiconductor technology, a capacitor is a very important basic device. Among various capacitor configurations, the MIM configuration and the MOM configuration are common capacitor configurations in which the insulating material is inserted between metal plates as electrodes to form a capacitor unit. In the MIM capacitor configuration, the insulator is disposed between the upper electrode and the lower electrode stacked vertically. In the MOM capacitor configuration or the like, oxide or nitride as the insulator is disposed between two adjacent electrodes in the horizontal direction.

As the performance of semiconductor devices continues to improve, the requirements for the capacitance of the capacitor device are also increased. In order to have higher capacitance, the capacitor device may include a plurality of capacitor units. As a result, the layout area and the process complexity of the capacitor device are increased. Therefore, how to effectively increase the capacitance per unit area of a capacitor device is an important issue in semiconductor technology.

### SUMMARY

The present invention provides a capacitor device and a manufacturing method thereof, wherein a MIM capacitor unit and a MOM capacitor unit or the like are integrated in one capacitor device.

The capacitor device of present invention includes a first electrode, a second electrode, an insulating layer, a first dielectric layer, a second dielectric layer, a third electrode and a fourth electrode. The first electrode is disposed on a substrate. The second electrode is disposed on the first electrode. The insulating layer is disposed between the first electrode and the second electrode. The first dielectric layer is disposed on the substrate and covers the first electrode, the second electrode and the insulating layer. The second dielectric layer is disposed on the first dielectric layer. The third electrode and the fourth electrode are disposed in the second dielectric layer and separated from each other. The third electrode is electrically connected to the first electrode, and the fourth electrode is electrically connected to the second electrode.

In an embodiment of the capacitor device of the present invention, the second electrode and the insulating layer expose a part of the first electrode.

In an embodiment of the capacitor device of the present invention, the capacitor device further includes a cap layer disposed between the first dielectric layer and the first electrode, between the first dielectric layer and the second electrode, and between the first dielectric layer and the insulating layer.

In an embodiment of the capacitor device of the present invention, a material of the cap layer comprises silicon nitride (SiN), silicon carbonitride (SiCN) or silicon oxynitride (SiON).

In an embodiment of the capacitor device of the present invention, the capacitor device further includes an etching stop layer disposed between the first dielectric layer and the second dielectric layer.

In an embodiment of the capacitor device of the present invention, the third electrode and the fourth electrode extend into the etching stop layer.

In an embodiment of the capacitor device of the present invention, a material of the second dielectric layer comprises a high dielectric constant (high-k) material.

In an embodiment of the capacitor device of the present invention, the capacitor device further includes a buffer layer disposed between the substrate and the first electrode.

In an embodiment of the capacitor device of the present invention, the third electrode and the fourth electrode are each a comb-shaped electrode.

In an embodiment of the capacitor device of the present invention, the capacitor device further includes a first conductive via and a second conductive via, wherein the first conductive via is disposed between the first electrode and the third electrode, and the second conductive via is disposed between the second electrode and the fourth electrode.

The manufacturing method of the capacitor device of present invention includes the following steps. A first electrode is formed on a substrate. An insulating layer is formed on the first electrode. A second electrode is formed on the insulating layer. A first dielectric layer is formed on the substrate, wherein the first dielectric layer covers the first electrode, the second electrode and the insulating layer. A second dielectric layer is formed on the first dielectric layer. A third electrode and a fourth electrode are formed in the second dielectric layer, wherein the third electrode and the fourth electrode are separated from each other. The third electrode is electrically connected to the first electrode, and the fourth electrode is electrically connected to the second electrode.

In an embodiment of manufacturing method of the capacitor device of the present invention, the second electrode and the insulating layer expose a part of the first electrode.

In an embodiment of manufacturing method of the capacitor device of the present invention, a forming method of the first electrode, the insulating layer and the second electrode includes the following steps. A first electrode material layer, an insulating material layer and a second electrode material layer are formed on the substrate sequentially. A first patterning process is performed on the first electrode material layer, the insulating material layer and the second electrode material layer. A second patterning process is performed on the insulating material layer and the second electrode material layer.

In an embodiment of manufacturing method of the capacitor device of the present invention, the manufacturing method further includes forming a cap layer on the substrate to cover the first electrode, the second electrode and the insulating layer after forming the second electrode and before forming the first dielectric layer.

In an embodiment of manufacturing method of the capacitor device of the present invention, the manufacturing method further includes forming an etching stop layer on the first dielectric layer after forming the first dielectric layer and before forming the second dielectric layer.

In an embodiment of manufacturing method of the capacitor device of the present invention, the third electrode and the fourth electrode extend into the etching stop layer.

In an embodiment of manufacturing method of the capacitor device of the present invention, the manufacturing method further includes forming a first conductive via and a second conductive via in the first dielectric layer after forming the first dielectric layer, wherein the first conductive via is located between the first electrode and the third electrode, and the second conductive via is located between the second electrode and the fourth electrode.

In an embodiment of manufacturing method of the capacitor device of the present invention, a forming method of the third electrode, the fourth electrode, the first conductive via and the second conductive via includes the following steps. A first through hole and a second through hole are formed in the second dielectric layer and the first dielectric layer, wherein the first through hole exposes a part of the first electrode, and the second through hole exposes a part of the second electrode. A first trench and a second trench are formed in the second dielectric layer, wherein the first trench is communicated with the first through hole, and the second trench is communicated with the second through hole. A conductive material is filled in the first through hole, the second through hole, the first trench and the second trench.

In an embodiment of manufacturing method of the capacitor device of the present invention, a shape of the first trench and a shape of the second trench are each comb-shaped from a top view above the substrate.

In an embodiment of manufacturing method of the capacitor device of the present invention, the manufacturing method further includes forming a buffer layer on the substrate before forming the first electrode.

Based on the above, the capacitor device of the present invention includes a MIM capacitor unit and a MOM capacitor unit or the like electrically connected to each other, and the MOM capacitor unit or the like is stacked on the MIM capacitor unit. Therefore, the capacitance per unit area of the capacitor device may be effectively increased, and the process of the MIM capacitor unit and the process of the MOM capacitor unit or the like may be integrated together.

### BRIEF DESCRIPTION OF THE DRAWINGS

FIGS. 1A to 1D are schematic cross-sectional views of the manufacturing process of the capacitor device of the embodiment of the present invention.

FIG. 2 is a top view of the MOM capacitor unit or the like in FIG. 1D.

### DESCRIPTION OF THE EMBODIMENTS

The embodiments are listed below and described in detail with the accompanying drawings, but the provided embodiments are not intended to limit the scope of the present invention. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

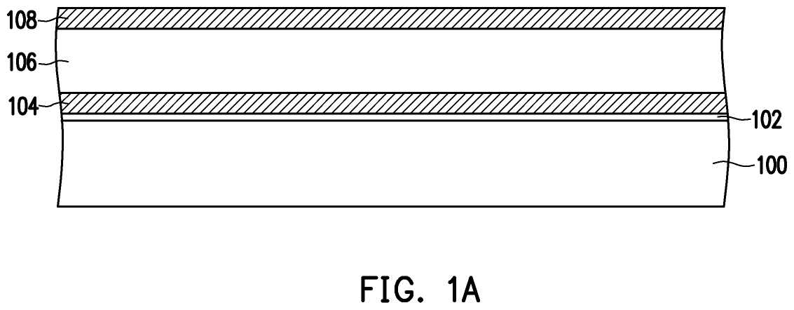

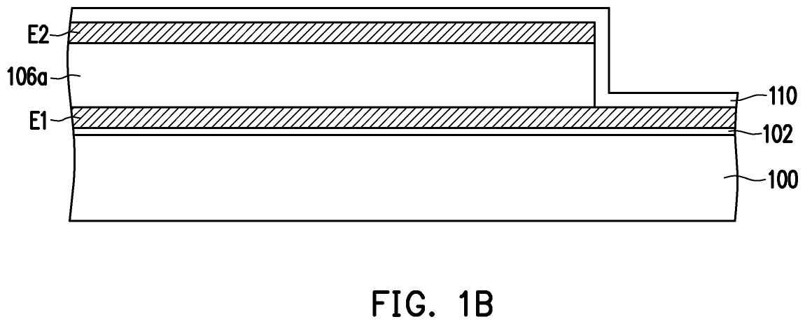

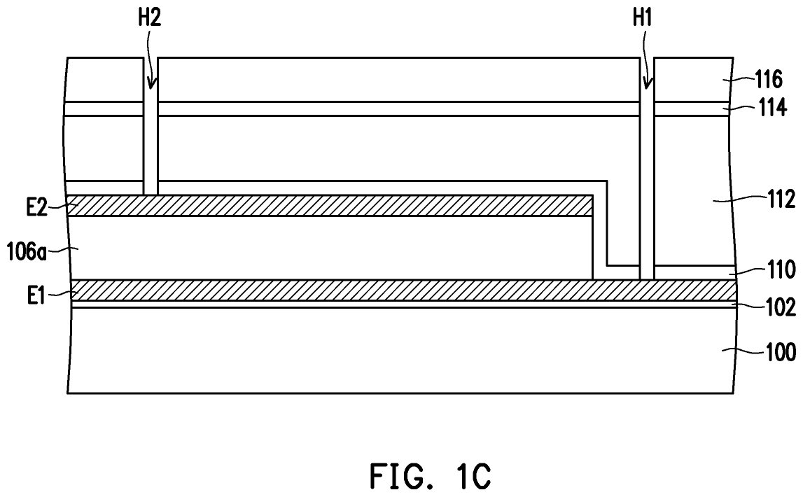

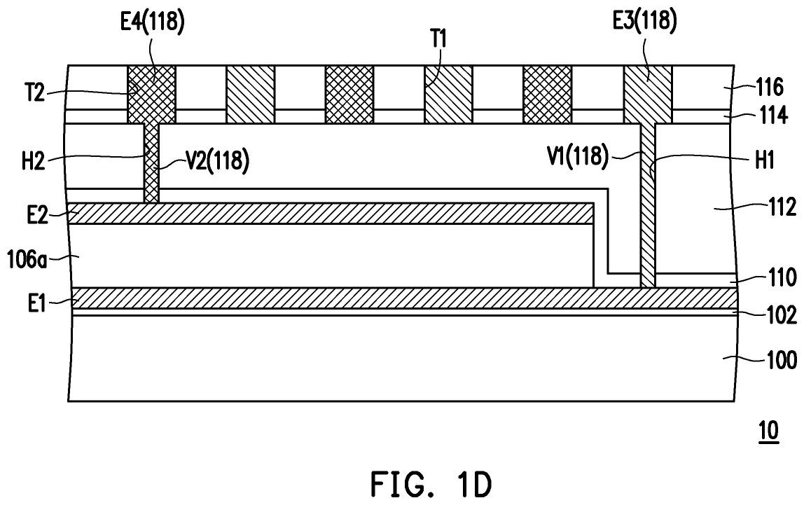

In addition, “high dielectric constant (high-k) material” in the text may refer to a dielectric material with a dielectric constant greater than 4 in the present technical field. FIGS. 1A to 1D are schematic cross-sectional views of the manufacturing process of the capacitor device of the embodiment of the present invention. In the present embodiment, the process of a MIM capacitor unit is integrated with the process of a MOM capacitor unit or the like, so that the formed capacitor device may include a MIM capacitor unit and a MOM capacitor unit or the like disposed in stack and electrically connected to each other, thereby increasing the capacitance per unit area of the capacitor device. The present invention will be described in detail below.

Referring to FIG. 1A, a substrate 100 is provided. In the present embodiment, the substrate 100 is a dielectric substrate, which is, for example, a dielectric layer formed on a silicon substrate and covering semiconductor devices on the silicon substrate. Then, a buffer layer 102 may be formed on the substrate 100. In the present embodiment, the material of the buffer layer 102 is, for example, SiN, SiCN or SiON. Afterwards, a first electrode material layer 104, an insulating material layer 106 and a second electrode material layer 108 are sequentially formed on the buffer layer 102. The first electrode material layer 104 is used to form the lower electrode of the capacitor unit, the second electrode material layer 108 is used to form the upper electrode of the capacitor unit, and the insulating material layer 106 is used to form the insulator between the upper electrode and the lower electrode. In other embodiments, the buffer layer 102 may be omitted depending on the actual situation.

The first electrode material layer 104 may be a metal layer or a composite layer composed of a metal layer and a metal nitride layer, but the present invention is not limited thereto. For example, the first electrode material layer 104 may be a titanium (Ti) layer or a composite layer composed of a titanium layer and a titanium nitride (TiN) layer. The material of the insulating material layer 106 may be a high-k material. For example, the insulating material layer 106 may be a composite layer composed of a zirconium oxide (ZrO₂) layer, an aluminum oxide (Al₂O₃) layer, and another ZrO₂ layer, but the present invention is not limited thereto. The second electrode material layer 108 may be a metal layer or a composite layer composed of a metal layer and a metal nitride layer, but the present invention is not limited thereto. For example, the second electrode material layer 108 may be a Ti layer or a composite layer composed of a Ti layer and a TiN layer.

Referring to FIG. 1B, a first patterning process may be performed on the first electrode material layer 104, the insulating material layer 106 and the second electrode material layer 108. A part of the first electrode material layer 104, a part of the insulating material layer 106 and a part of the second electrode material layer 108 are removed to define a region where a capacitor to be formed. After defining the region where a capacitor to be formed, a second patterning process is performed on the second electrode material layer 108 and the insulating material layer 106 to remove a part of the insulating material layer 106 and a part of the second electrode material layer 108. In this way, a first electrode E1 formed by the first electrode material layer 104, an insulating layer 106a formed by the insulating material layer 106 and a second electrode E2 formed by the second electrode material layer 108 may be formed on the substrate 100, and the second electrode E2 and the insulating layer 106a expose a part of the first electrode E1.

The first electrode E1, the insulating layer 106a and the second electrode E2 may constitute a MIM capacitor unit in the present embodiment. In addition, the first electrode E1 may be connected to the conductive devices (not shown) in the substrate 100, so that the MIM capacitor unit may be electrically connected to the semiconductor devices on the silicon substrate. After forming the first electrode E1, the insulating layer 106a and the second electrode E2, a cap layer 110 may be formed on the substrate 100 to cover the first electrode E1, the insulating layer 106a and the second electrode E2. In the present embodiment, the material of the cap layer 110 is, for example, SiN, SiCN or SiON, but the present invention is not limited thereto. The cap layer 110 may prevent the first electrode E1, the insulating layer 106a and the second electrode E2 from being damaged in subsequent processes. In other embodiments, the cap layer 110 may be omitted depending on the actual situation.

Referring to FIG. 1C, a first dielectric layer 112 is formed on the substrate 100. In the present embodiment, the first dielectric layer 112 is formed on the cap layer 110 to cover the first electrode E1, the insulating layer 106a and the second electrode E2. The first dielectric layer 112 may be used as an inter-metal (IMD) dielectric layer in the capacitor device of the present embodiment. The material of the first dielectric layer 112 is, for example, silicon oxide, but the present invention is not limited thereto. For example, the material of the first dielectric layer 112 may be phosphoric silicate glass (PSG) or undoped silicate glass (undoped silicate glass, USG). After forming first dielectric layer 112, depending on actual requirements, a planarization process may be performed on the first dielectric layer 112 to ensure that the first dielectric layer 112 has a planar surface. The planarization process is, for example, a chemical mechanical polishing (CMP) process.

Then, an etching stop layer 114 and a second dielectric layer 116 are formed on the first dielectric layer 112 in sequence. The material of the etching stop layer 114 may be SiN, SiCN or SiON. The etching stop layer 114 may be a single layer or a composite layer constituted by a plurality of layers, and the present invention does not limit this. In an embodiment, the material of the second dielectric layer 116 is, for example, a high-k material. For example, the material of the second dielectric layer 116 may be SiN, but the present invention is not limited thereto. In other embodiments, the material of the second dielectric layer 116 may be silicon oxide. That is, the second dielectric layer 116 is used to form the insulator between two adjacent electrodes in the MOM capacitor unit or the like.

Afterwards, at least one first through hole H1 and at least one second through hole H2 are formed in the second dielectric layer 116, the etching stop layer 114, the first dielectric layer 112 and the cap layer 110. The first through hole H1 exposes a part of the first electrode E1, and the second through hole H2 exposes a part of the second electrode E2. Depending on the actual process conditions, the first through hole H1 and the second through hole H2 may be formed in the same or different process steps, and the present invention does not limit this.

Referring to FIG. 1D, a patterning process is performed to form a first trench T1 and a second trench T2 in the second dielectric layer 116 and the etching stop layer 114. In the present embodiment, the first trench T1 and the second trench T2 are formed in the same patterning process. The first trench T1 is formed above the first through hole H1 and communicated with the first through hole H1. The second trench T2 is formed above the second through hole H2 and communicated with the second through hole H2. The detailed forming method of the first through hole H1, the second through hole H2, the first trench T1 and the second trench T2 are well known to those skilled in the art and will not be described further here.

In the present embodiment, from the top view above the substrate 100, the shape of the first trench T1 and the shape of the second trench T2 are each comb-shaped. In addition, in the plane direction of the second dielectric layer 116, the first trench T1 and the second trench T2 are alternately arranged.

In the present embodiment, the etching stop layer 114 is formed between the first dielectric layer 112 and the second dielectric layer 116, thereby ensuring that the bottom of the first trench T1 and the bottom of the second trench T2 are formed on the surface of the first dielectric layer 112. In other embodiments, the bottom of the first trench T1 and the bottom of the second trench T2 may be formed in the etching stop layer 114.

Afterwards, a conductive material 118 is filled into the first through hole H1, the second through hole H2, the first trench T1 and the second trench T2. In this way, a capacitor device 10 of the present embodiment is formed. The conductive material 118 may be a metal material. In the present embodiment, the conductive material 118 may be copper (Cu), but the present invention is not limited thereto. The conductive material 118 located in the first trench T1 may form a third electrode E3, and the conductive material 118 located in the second trench T2 may form a fourth electrode E4. In addition, the conductive material 118 located in the first through hole H1 may form a first conductive via V1 for electrically connecting the first electrode E1 and the third electrode E3, and the conductive material 118 located in the second through hole H2 may form a second conductive via V2 for electrically connecting the second electrode E2 and the fourth electrode E4.

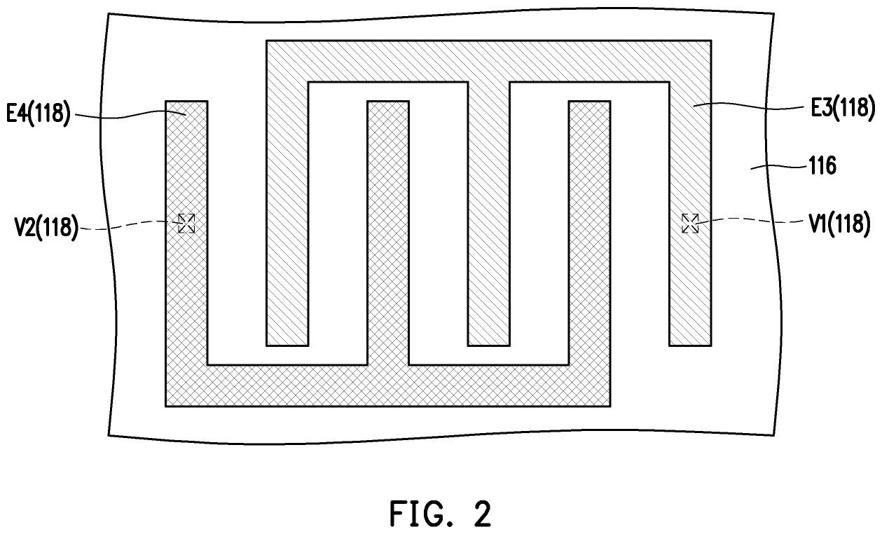

As shown in FIG. 2, the third electrode E3 and the fourth electrode E4 are each comb-shaped electrodes and are alternately arranged in the plane direction of the second dielectric layer 116. In this way, the third electrode E3, the fourth electrode E4 and the second dielectric layer 116 between the third electrode E3 and the fourth electrode E4 may constitute a MOM capacitor unit or the like, which may be electrically connected to the MIM capacitor unit constituted by the first electrode E1, the insulating layer 106a and the second electrode E2 through the first conductive via V1 and the second through hole H2

In the present embodiment, the third electrode E3 and the fourth electrode E4 are each a comb-shaped electrode, but the present invention is not limited thereto. In other embodiments, the third electrode E3 and the fourth electrode E4 may be electrodes of other shapes that are alternately arranged in the plane direction of the second dielectric layer 116.

In the present embodiment, the first electrode E1 is electrically connected to the third electrode E3 through the first conductive via V1, so the first electrode E1 and the third electrode E3 may be electrically connected to a first common voltage source (one of the high voltage source and the low voltage source). In addition, the second electrode E2 is electrically connected to the fourth electrode E4 through the second conductive via V2, so the second electrode E2 and the fourth electrode E4 may be electrically connected to the second common voltage source (the other one of the high voltage source and the low voltage source).

As shown in FIG. 1D, the capacitor device 10 of the present embodiment includes a MIM capacitor unit constituted by the first electrode E1, the insulating layer 106a and the second electrode E2 and a MOM capacitor unit or the like constituted by the third electrode E3, the second dielectric layer 116 and the fourth electrode E4 disposed in stack. Therefore, the capacitor device 10 may have a higher capacitance per unit area without occupying too much layout area.

In addition, in the present embodiment, the capacitor device 10 may be constituted by only three layers of metal, i.e., a first metal layer constituting the first electrode E1, a second metal layer constituting the second electrode E2 and a third metal layer constituting the third electrode E3 and the fourth electrode E4, thus effectively reducing the thickness of the capacitor device 10.

In addition, in the manufacturing process of the capacitor device 10, the process of the MIM capacitor unit and the process of the MOM capacitor unit or the like are integrated, so the use of the photomasks may be effectively reduced, thereby reducing process complexity and production costs.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A capacitor device, comprising:
a first electrode, disposed on a substrate;
a second electrode, disposed on the first electrode;
an insulating layer, disposed between the first electrode and the second electrode;
a first dielectric layer, disposed on the substrate and covering the first electrode, the second electrode and the insulating layer;
a second dielectric layer, disposed on the first dielectric layer; and
a third electrode and a fourth electrode, disposed in the second dielectric layer and separated from each other,
wherein the third electrode is electrically connected to the first electrode, and the fourth electrode is electrically connected to the second electrode.

2. The capacitor device of claim 1, wherein the second electrode and the insulating layer expose a part of the first electrode.

3. The capacitor device of claim 1, further comprising a cap layer disposed between the first dielectric layer and the first electrode, between the first dielectric layer and the second electrode, and between the first dielectric layer and the insulating layer.

4. The capacitor device of claim 3, wherein a material of the cap layer comprises silicon nitride (SiN), silicon carbonitride (SiCN) or silicon oxynitride (SiON).

5. The capacitor device of claim 1, further comprising an etching stop layer disposed between the first dielectric layer and the second dielectric layer.

6. The capacitor device of claim 5, wherein the third electrode and the fourth electrode extend into the etching stop layer.

7. The capacitor device of claim 1, wherein a material of the second dielectric layer comprises a high dielectric constant (high-k) material.

8. The capacitor device of claim 1, further comprising a buffer layer disposed between the substrate and the first electrode.

9. The capacitor device of claim 1, wherein the third electrode and the fourth electrode are each a comb-shaped electrode.

10. The capacitor device of claim 1, further comprising a first conductive via and a second conductive via, wherein the first conductive via is disposed between the first electrode and the third electrode, and the second conductive via is disposed between the second electrode and the fourth electrode.

11. A manufacturing method of a capacitor device, comprising:
forming a first electrode on a substrate;
forming an insulating layer on the first electrode;
forming a second electrode on the insulating layer;
forming a first dielectric layer on the substrate, wherein the first dielectric layer covers the first electrode, the second electrode and the insulating layer;
forming a second dielectric layer on the first dielectric layer; and
forming a third electrode and a fourth electrode in the second dielectric layer, wherein the third electrode and the fourth electrode are separated from each other,
wherein the third electrode is electrically connected to the first electrode, and the fourth electrode is electrically connected to the second electrode.

12. The manufacturing method of claim 11, wherein the second electrode and the insulating layer expose a part of the first electrode.

13. The manufacturing method of claim 12, wherein a forming method of the first electrode, the insulating layer and the second electrode comprises:
forming a first electrode material layer, an insulating material layer and a second electrode material layer on the substrate sequentially;
performing a first patterning process on the first electrode material layer, the insulating material layer and the second electrode material layer; and
performing a second patterning process on the insulating material layer and the second electrode material layer.

14. The manufacturing method of claim 11, further comprising forming a cap layer on the substrate to cover the first electrode, the second electrode and the insulating layer after forming the second electrode and before forming the first dielectric layer.

15. The manufacturing method of claim 11, further comprising forming an etching stop layer on the first dielectric layer after forming the first dielectric layer and before forming the second dielectric layer.

16. The manufacturing method of claim 15, wherein the third electrode and the fourth electrode extend into the etching stop layer.

17. The manufacturing method of claim 11, further comprising forming a first conductive via and a second conductive via in the first dielectric layer after forming the first dielectric layer, wherein the first conductive via is located between the first electrode and the third electrode, and the second conductive via is located between the second electrode and the fourth electrode.

18. The manufacturing method of claim 17, wherein a forming method of the third electrode, the fourth electrode, the first conductive via and the second conductive via comprises:
forming a first through hole and a second through hole in the second dielectric layer and the first dielectric layer, wherein the first through hole exposes a part of the first electrode, and the second through hole exposes a part of the second electrode;
forming a first trench and a second trench in the second dielectric layer, wherein the first trench is communicated with the first through hole, and the second trench is communicated with the second through hole; and
filling a conductive material in the first through hole, the second through hole, the first trench and the second trench.

19. The manufacturing method of claim 18, wherein a shape of the first trench and a shape of the second trench are each comb-shaped from a top view above the substrate.

20. The manufacturing method of claim 11, further comprising forming a buffer layer on the substrate before forming the first electrode.
